(19) United States
(12) Patent Application Publication
(10) Pub. No.: US 2025/0311130 A1
(43) Pub. Date: Oct. 2, 2025

(54) HOUSING WITH SEAL

(71) Applicant: POLYTEC PLASTICS Germany GmbH & Co. KG, Lohne (DE)

(72) Inventors: Walter van GILST, PC Goes (NL); Jens HUCKLE, Graben-Neudorf (DE); Tobias BURKERT, Osnabrück (DE); Michael BUCK, Damme (DE); Jorge SOARES, Wettringen (DE); Christoph LESON, Dinklage (DE); Christian BERDING, Lohne (DE)

(73) Assignee: POLYTEC PLASTICS Germany GmbH & Co. KG, Lohne (DE)

(21) Appl. No.: 19/091,361

(22) Filed: Mar. 26, 2025

(30) Foreign Application Priority Data
Mar. 26, 2024 (DE) 10 2024 108 587.8

(51) Int. Cl. H05K 5/06

(52) U.S. Cl. CPC H05K 5/061; H05K 5/069

(57) ABSTRACT

There is a housing preferably for accommodating electrical components. The housing has the following: (A) at least one first housing part and at least one second housing part, which form a closed housing when assembled, (B) at least the first housing part has a circumferential edge or circumferential contour in an edge area, (C) at least one compressible element, which is at least arranged on the circumferential edge or in or on the circumferential contour, and which is arranged between the first housing part and the second housing part in the assembled state, and (D) and at least one first electrically conductive layer. The first electrically conductive layer covers the inside of the first housing part in the assembled state of the housing.

### CROSS-REFERENCE TO A RELATED APPLICATION

The present application claims priority on German Application No. DE 1 2024 108 587.8, filed Mar. 26, 2024, which is incorporated herein by reference in its entirety.

### FIELD OF THE DISCLOSURE

The disclosure relates to a housing preferably for accommodating electrical components.

### DESCRIPTION OF THE RELATED ART

Housings are known for accommodating electrical components, for example in a motor vehicle, which have at least a first housing part and at least a second housing part that form a closed housing when assembled. At least the first housing part has a circumferential edge or circumferential contour in the edge region and at least one circumferential seal is provided, which is arranged on the circumferential edge or in or on the circumferential contour and which is arranged between the first housing part and the second housing part in the assembled state. Due to these seals, the housing is sealed to the outside. For example, liquids, dirt or dust from the outside cannot penetrate the inside of the housing and thus damage the components. On the other hand, it is also possible to prevent liquids that escape from the components inside the housing from escaping from the housing, for example.

It is also known to electromagnetically shield electrical components in a housing, for example to reduce interference. Such measures are known as electromagnetic compatibility (EMC).

In order to electromagnetically shield devices with housings, the first and second housing parts must either be electrically conductive themselves or have an electrically conductive layer, such as a coating. In addition, a seal that is electrically conductive is often provided in such cases. Expensive conductive fillers are often added to the seal so that the first and second housing parts can be electrically conductively connected to each other via the seal, or electrically conductive connecting elements, e.g. screws, are used at small distances from each other and in correspondingly large numbers to electrically connect the two housing parts in order to create sufficient electromagnetic shielding of the components in the housing, also at the interfaces of the housing parts. These prior art solutions are therefore very expensive and have reduced electromagnetic shielding at the housing interfaces due to the lower electrical conductivity of filled electrically conductive seals or due to the gaps between the screws for the electrical connection of the housing parts.

### SUMMARY OF THE DISCLOSURE

The present disclosure provides a housing for accommodating electrical components, which can be manufactured in a simple and cost-effective manner. Features of the housing are set forth in claim 1.

According to the present disclosure, a housing is preferably provided for accommodating electrical components, comprising
at least one first housing part and at least one second housing part, which form a closed housing when assembled,
wherein at least the first housing part has a circumferential edge or circumferential contour in the edge area,
at least one compressible element which is at least arranged on the circumferential edge or in or on the circumferential contour and which is arranged between the first housing part and the second housing part in the assembled state.

### BRIEF DESCRIPTION OF THE DISCLOSURE

In the following, embodiments of the present disclosure are described in more detail with reference to the Figures.

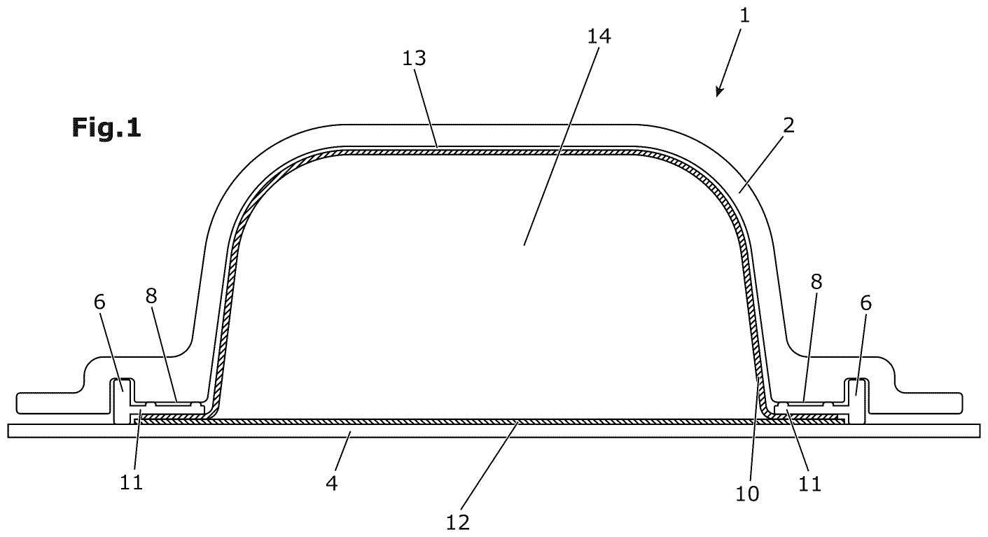

FIG. 1 shows a housing according to the present disclosure,

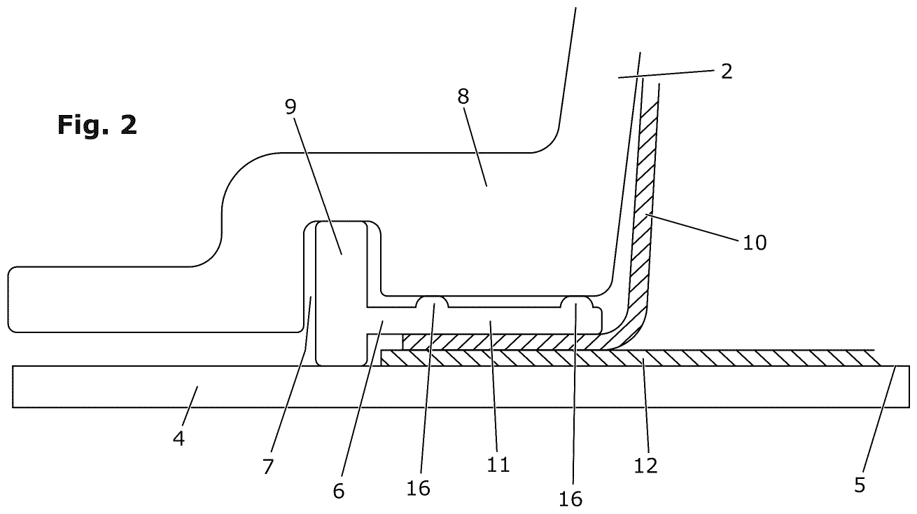

FIG. 2 shows a detail of the housing according to FIG. 1 with seal and electrically conductive layer,

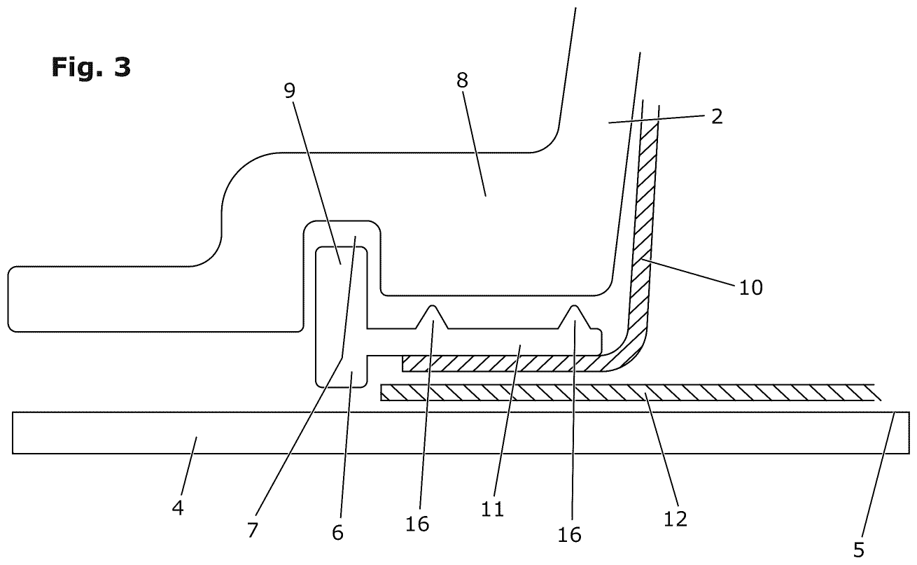

FIG. 3 shows the embodiment according to FIG. 2 in a non-assembled state,

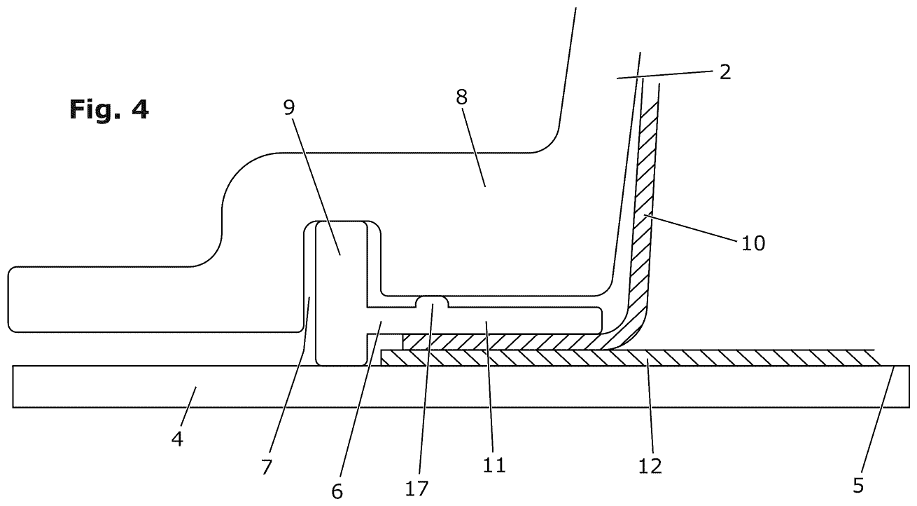

FIG. 4 shows an alternative embodiment in which the seal has only one projection,

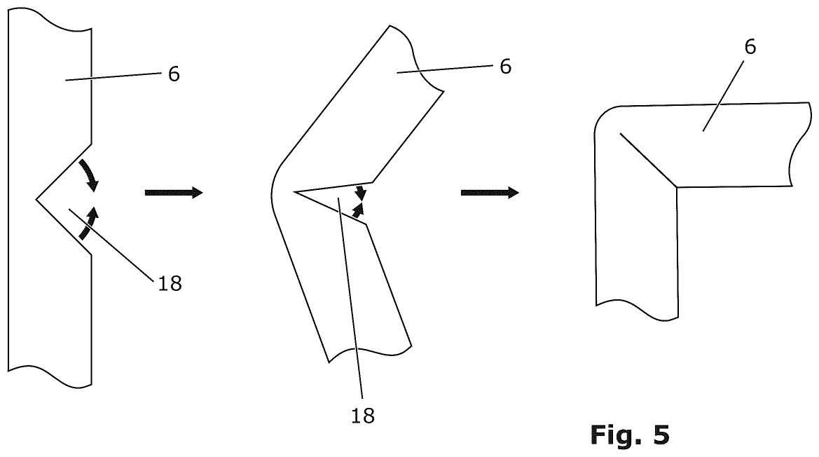

FIG. 5 shows a corner area of the seal, as it can be provided in the area of a corner of the housing,

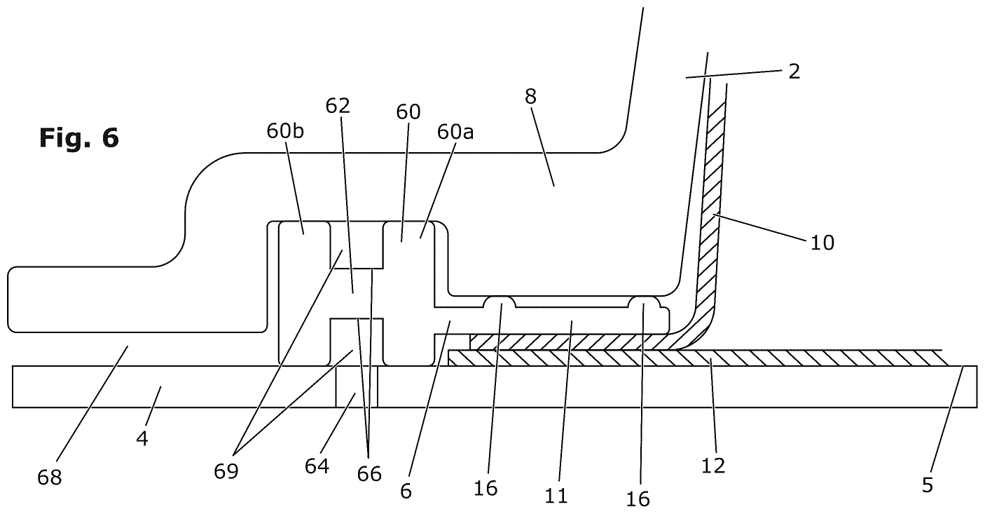

FIG. 6 shows a further embodiment of a seal according to the disclosure whose profile design allows an advantageous leak test of the seal,

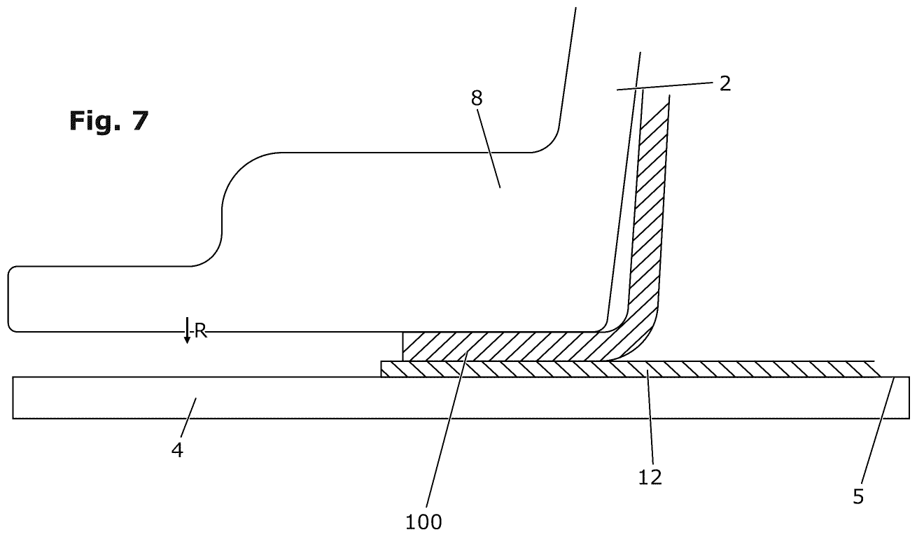

FIG. 7 shows a further embodiment in which the compressible element and the at least one first electrically conductive layer form a common layer,

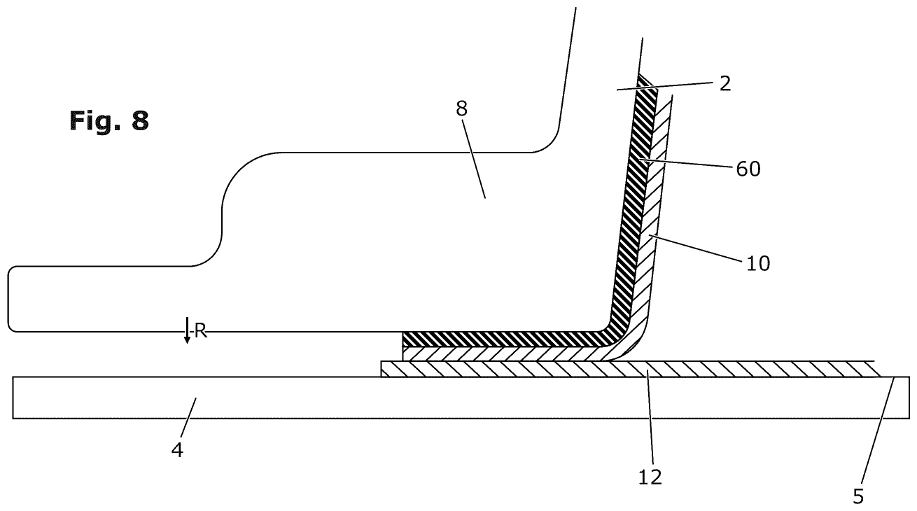

FIG. 8 shows a further embodiment in which the at least one compressible element 60 and the at least one first electrically conductive layer 10 are designed as a flat composite material,

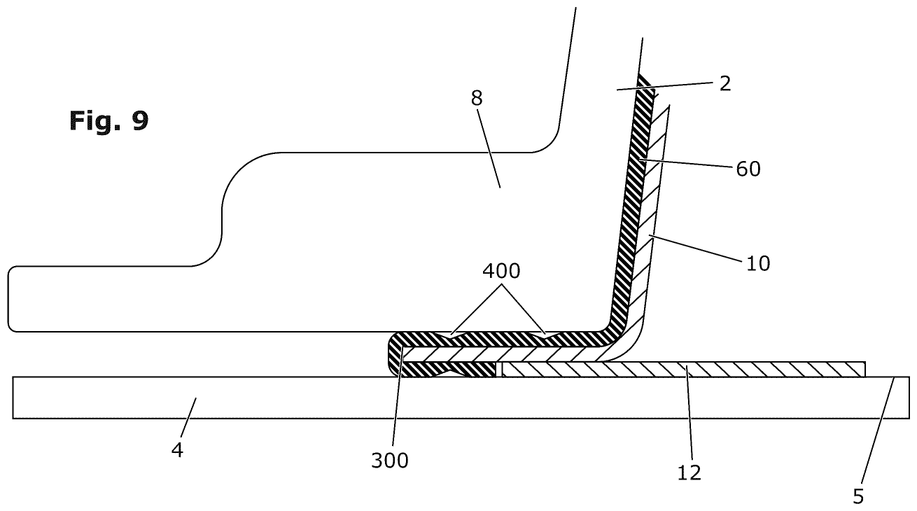

FIG. 9 shows a further embodiment, in which the compressible element designed as a layer at least partially wraps around the at least one electrically conductive layer, in particular in the region of the circumferential edge or in or on the circumferential contour,

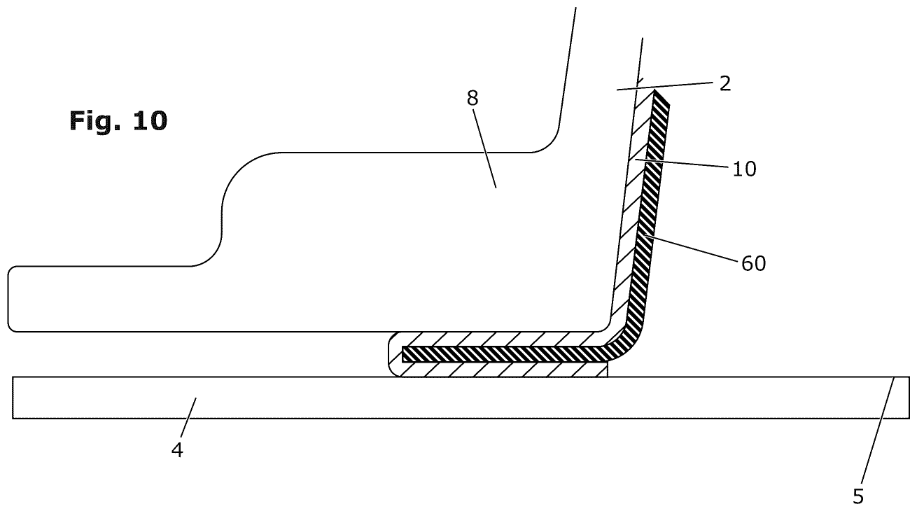

FIG. 10 shows a further embodiment, in which the at least one electrical conductive layer 10 at least partially wraps around the at least one compressible layer 60, in particular in the region of the circumferential edge 8 or in or on the circumferential contour,

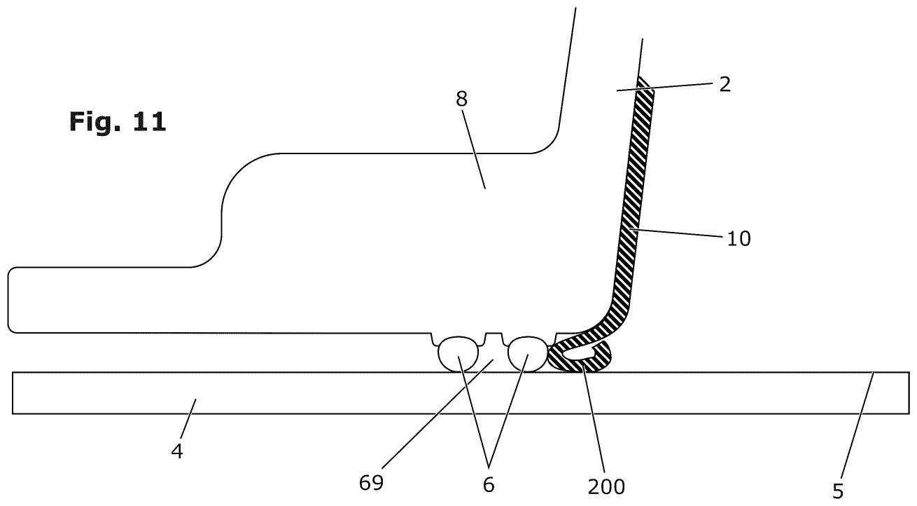

FIG. 11 shows a further embodiment in which at least one edge region 200 of the first electrically conductive layer 10 is rolled up or folded over.

### DETAILED DESCRIPTION OF THE DISCLOSURE

The disclosure advantageously provides for at least a first electrically conductive layer, wherein in the assembled state of the housing the electrically conductive layer covers the inside of the first housing part.

In this way, for example, the first and/or second housing part can be designed to be non-conductive. The housing can be made of plastic, for example. This means that simple housings and seals can be produced without the housing or seal having to have additional conductive fillers.

The compressible element can have an elastic material such as an elastomer.

With the help of the compressible element, the housing can be sealed against the environment. For example, liquids, dirt or dust from the outside cannot penetrate the inside of the housing and thus the components inside the housing are protected.

The first electrically conductive layer can contact both the first housing part and the second housing part in the area of the circumferential edge.

At least one edge area of the first electrically conductive layer can be rolled up or folded over.

The first electrically conductive layer can contact both the first housing part and the second housing part by the rolled-up or folded-over edge area.

The first electrically conductive layer can be in contact with the compressible element by the rolled-up or folded-over edge area, the compressible element being preferably designed as a seal.

An elastic part can be arranged in the rolled-up or folded-over edge area, by means of which the electrically conductive layer can be pressed against both the first housing part and the second housing part.

The at least one compressible element and the at least one first electrically conductive layer can form a common layer, which is designed as a flat material, so that the layer designed as a flat material can be compressed in the thickness direction.

The at least one compressible element and the at least one first electrically conductive layer can form a composite flat material, wherein at least the compressible element formed as a layer and/or the first electrically conductive layer can be pressed in the thickness direction.

The at least one electrically conductive layer at least partially wraps around the at least one compressible element designed as a compressible layer, in particular in the region of the circumferential edge or in or on the circumferential contour.

The at least one compressible element designed as a compressible layer can at least partially wrap around the at least one electrically conductive layer, in particular in the region of the circumferential edge or in or on the circumferential contour.

The at least one compressible element designed as a compressible layer can have notches.

The at least one electrically conductive layer can at least partially wrap around the at least one compressible element designed as a compressible layer, in particular in the region of the circumferential edge or in or on the circumferential contour.

The at least one compressible element can be designed as a seal, preferably as a circumferential seal, whereby the seal and the first electrically conductive layer are in contact with each other.

The seal designed as a circumferential seal can preferably be connected to a circumferential edge area of the first electrical layer, so that the seal and the layer together form a surface that can be placed on the first housing part, wherein the circumferential seal can then be arranged on the circumferential edge of the first housing part. In this way, in the assembled state, not only can the seal be arranged between the first housing part and the second housing part, but also a part of the first electrically conductive layer.

The seal can be adhesively bonded to the first housing part. The seal can be set on the first housing part.

The contact between the seal and the electrically conductive layer can be established by at least partially laying one on top of the other and/or a form-fit and/or force-fit and/or adhesive connection can exist as the contact. The seal can be connected to the electrically conductive layer by bonding and/or form fit.

The electrically conductive layer can, for example, be connected to the seal by means of an adhesive layer.

The seal and the electrically conductive layer can form a common assembly.

The electrically conductive layer can, for example, take the form of a film, sheet, fabric, fleece, layer or a combination of the aforementioned forms. The electrically conductive layer can consist at least partially of a metallic material or carbon-containing material.

The seal can be at least partially compressed in the assembled state, at least in the area where the seal is in contact with the electrically conductive layer.

By partially compressing the seal, particularly in the area in which the electrically conductive layer is in contact with the seal, local compression can be achieved in the assembled state, whereby tolerance deviations, including in the form of unevenness between the first housing part and the second housing part, can be compensated.

If the electrically conductive layer is directly connected to the seal, positive positioning in the housing is also possible.

The seal preferably includes an elastic material, such as an elastomer. The elastic material can be elastically deformable. This means that the seal returns to its original state after subjection to a load.

A seal in the sense of the present disclosure is understood to be an element that prevents or limits unwanted material transfers from one location to another. In this case, the seal is intended in particular to prevent liquid substances or dust from entering or leaving the housing.

The seal can have at least one connection area, in particular a sealing tab, with which the electrically conductive layer is in contact.

The connection area is simply an area of the seal that is in contact with the electrically conductive layer.

The seal, in particular the connection area, and the electrically conductive layer can be arranged to at least partially overlap each other in the assembled state.

The connection area can be an area molded onto the seal, which in the assembled state is arranged on the side of the seal facing the inside of the housing.

The connection area can be a part of the seal which preferably has a lower height in relation to the remaining part of the seal, the connection area preferably being a tab.

The connection area can extend over the entire width of the seal, i.e. over the surface of the seal facing the second housing part.

The at least one connection area can be a circumferential part of the seal. Several circumferential connection areas can be provided, which preferably have essentially uniform spacing from one another along the sealing path.

The seal, in particular the connection area, can be at least partially compressed in the assembled state.

The seal, in particular the connection area, can have at least one, preferably at least two projections.

The at least one projection can be at least partially compressed in the assembled state. The fact that the seal and the electrically conductive layer preferably overlap one another and are preferably arranged in the area in which the seal has projections and these projections can be pressed together in the assembled state ensures that the electrically conductive layer is always in contact with the second housing part or a further electrically conductive layer of the second housing part.

The at least one projection can protrude in the direction in which the force acting on the seal acts in the assembled state.

The second housing part can be electrically conductive. The second housing part can be a housing part made of metal, for example.

Alternatively or additionally, a second electrically conductive layer can be provided, which covers the inside of the second housing part when assembled.

The first and second electrically conductive layers can be connected to each other in the assembled state.

The first and second electrically conductive layers can also be connected to each other in the non-assembled state.

In at least one area, the seal can consist of at least two spaced-apart sealing areas, between which at least one closed volume is formed, wherein at least one test pressure bore for the application of a differential pressure for the leak test of the seal can be provided between the at least two spaced-apart sealing areas.

The at least two spaced-apart sealing areas can be connected to one another via at least one web area, and the at least two spaced-apart sealing areas can preferably form an H-shaped cross-sectional profile (60) with the at least one web area.

A housing for accommodating at least one battery cell comprising at least one seal and at least one electrically conductive layer according to any one of claims 1 to 33 may be provided for sealing and electromagnetically shielding the at least one battery cell and electrical components accommodated in the battery housing.

The seal and the at least one electrically conductive layer according to any one of claims 1 to 33 may be provided for sealing and electromagnetically shielding the at least one battery cell and electrical components accommodated in the battery housing.

A seal for insertion in a housing according to claims 1-33 may be provided, wherein the seal may be a circumferential seal which may be connected to at least a first electrically conductive layer.

The circumferential seal can be connected to the circumferential edge area of the first electrically conductive layer.

The seal can have a connection area to which the electrically conductive layer is connected, and the connection area and the electrically conductive layer can preferably be arranged to overlap one another.

The seal as part of this disclosure can be manufactured in different ways. The seal can preferably be produced in a discontinuous molding process, for example in an elastomer injection molding process.

The at least one seal can preferably also be applied to one or more housing parts in liquid form, for example as a thermoplastic elastomer seal or hot-melt seal or also as a chemically cross-linking seal.

Furthermore, the seal can preferably be produced in a continuous shaping endless process, for example in a cost-effective elastomer extrusion process.

In order to be able to use a seal produced using the cost-effective extrusion process for the circumferential seal, it must either be possible to apply it to a housing part following the intended sealing path, particularly in corner areas, or the seal must be assembled from several pieces, which increases the costs and the number of interfaces.

In particular, wider seals or the preferably integral extruded seal according to the disclosure, which is preferably widened around the connection area to the electrically conductive layer, cannot be applied to one of the housing parts with increasing width, especially in the corner areas, without deforming the function-determining gasket cross-section.

In order to avoid functionally impairing deformations, particularly in the corner areas, the seal can preferably be cut in the corner areas over at least a portion of the width of the preferably existing connection area and only then be bent to form the corner or preferably be angled or deflected over an arcuate course or be formed into a predetermined curve so that no crushing or only minimal local deformation of the gasket material occurs in the corner areas of the seal due to the formation of the corner areas. The shape and size of the incision can be determined by testing so that the local deformation of the sealing material is minimized and, on the other hand, sufficient sealing is ensured over a sufficient sealing width in this area. Once the corner area has been formed, the electrically conductive layer can be attached to the seal by bonding and/or form fit.

The use of a housing according to any one of claims 1 to 37 provides for the temperature control of electrical components, such as electrical energy storages and/or electrical circuits.

The use according to claim 38 provides for the temperature control of electrical energy storages in the form of round cells, prismatic cells or flat, pocket-shaped battery cells.

The use according to claim 39 provides for the temperature control of energy storages of a stationary application or a motor vehicle, an aircraft or a ship.

FIG. 1 shows a housing 1 according to the disclosure. The housing is preferably suitable for accommodating electrical components. The housing 1 has at least one first housing part 2 and at least one second housing part 4 which, in the assembled state, enclose at least one volume for accommodating the preferably essentially electronic parts, wherein, for example, the first housing part 2 essentially accommodates the volume or the second housing part 4 essentially accommodates the volume or both housing parts each accommodate a portion of the volume.

Electrochemical energy storage cells, for example, can be provided as electrical components.

FIG. 1 shows the first and second housing parts 2, 4 in an assembled state. In this state, they form a closed housing 1, which forms an area 14 on the inside in which electrical components, for example, can be accommodated.

The first housing part 2 preferably has a circumferential edge 8. At least one compressible element can be provided, which can be arranged on the circumferential edge 8 and which, in the assembled state, can be arranged between the first housing part 2 and the second housing part 4. The compressible element can be a seal. The compressible element 6, which is designed as a seal, allows the housing 1 to be sealed against the environment. For example, liquids, solid contaminations or dust from the outside cannot penetrate the inside of the housing and thus the components inside the housing are protected. On the other hand, it is also possible to prevent liquids that emanate from the components inside the housing from escaping from the housing 1, for example.

The seal 6 can preferably be an elastic seal, in particular made of an elastomer. The seal 6 is in contact with at least a first electrically conductive layer 10, wherein in the assembled state the electrically conductive layer covers the inside 13 of the first housing part 2.

The connection between the seal 6 and the at least one first electrically conductive layer 10 can be by bonding and/or form-fit. The electrically conductive layer 10 can also simply be placed on the seal and when the first and second housing parts 2, 4 are assembled, the seal 6 and the electrically conductive layer 10 are pressed together.

The electrically conductive layer 10 does not have to be in direct contact with the inside 13 of the first housing part 2. However, the layer 10 should essentially run along the inside 13 of the second housing part, so that the electrically conductive layer 10 can contribute to the electromagnetic shielding of the housing. The elements to be electromagnetically shielded should therefore be arranged on the inside of the electrically conductive layer 10 inside the housing 1 in area 14.

In particular, the electrically conductive layer 10 is designed to overlap with at least part of the seal 6. For this purpose, the seal 6 preferably has a connection area 11, with which the electrically conductive layer 10 is preferably designed to overlap.

This can be illustrated in more detail in FIG. 2, for example, which shows a detail of FIG. 1.

For example, the first housing part 2 has a groove 7 in which a part 9 of the seal 6 is arranged.

Furthermore, in the embodiment shown in FIG. 2, the seal has two projections 16 in the region of the connection area 11, which are pressed together in the assembled state shown in FIG. 2.

In the assembled state, the protrusions 16 cause local compression of the electrically conductive layer 10.

In the illustrated embodiment, a second electrically conductive layer 12 is also provided, which runs along the inside 5 of the second housing part 4. The first electrically conductive layer 10 and the second electrically conductive layer 12 are pressed together by the local pressing, so that the electromagnetic shielding of the housing is preferably ensured to be essentially gap-free. For example, flatness tolerances of the housing can be compensated for in this way.

The second housing part 4 can also be electrically conductive itself and be a metal cover, for example. In this case, the second electrically conductive layer 12 could be omitted and the first electrically conductive layer could be pressed directly onto the second housing part.

FIG. 3 shows the embodiment according to FIG. 2 in a non-assembled state. In this state, it can be clearly seen that the protrusions 16 are not pressed together.

FIG. 4 shows a further embodiment, which differs from the previous embodiment in that only a single projection 17 is provided, which can be pressed together in the assembled state. Even a single projection of this kind can cause local compression in the assembled state, whereby tolerances between the housing part 2 and the housing part 4 can be compensated.

If the electrically conductive layer 10 is directly connected to the seal 6, a positive positioning in the housing can be achieved.

FIG. 5 shows a seal 6, wherein no sealing area 9 and no projections 16 are shown for reasons of simplicity. In particular, the seal can be cut in the corner area and only then be bent for the corner so that the sealing material is not crushed in the corner area of the seal. The shape and size of the incision can be determined by testing so that, on the one hand, no crushing of the material occurs and, on the other hand, sufficient sealing is ensured in this area. Once the bend has been formed, the electrically conductive layer 10 can be attached to the seal by bonding or form fit or force fit.

FIG. 6 shows an embodiment with an alternative embodiment for the seal 6. The seal 6 has an area which in turn has a cross-sectional profile 60 with an exemplary H-shaped contour, consisting of at least one inner sealing section 60a and at least one outer sealing section 60b, which are connected via a web area 62, wherein a test pressure opening 64 is provided between the inner sealing section 60a and the outer sealing section 60b of the exemplary H-shaped sealing profile 60 on the first and/or second housing part 2, 4 for the connection of compressed air or a differential pressure to the environment for the leak test of the seal. The web area 62, which is essentially not in contact with the first and/or second housing part 2, 4 and preferably has an opening for the test gas at at least one point along the sealing path, so that the test gas can preferably also flow up to the contact surfaces of the inner sealing section 60a and the outer sealing section 60b with the housing part opposite the test pressure opening 64 and thus leaks of the sealing sections 60a and 60b to both housing halves can be detected. The preferably at least one opening in the web area 62 that allows the test gas to pass through leads to the formation of a continuous test volume 69.

In order to be able to test the intended sealing of the sealing sections 60a, 60b as shown in FIG. 6, it must be ensured that the test gas flows from the outer sealing section 60b to the outside and from the inner sealing section 60a to the inside of the housing. In order to enable the test gas to flow out, preferably at least one channel 68, preferably in the form of at least one gap, is to be provided from the outer sealing section 60b to the environment and preferably at least one further channel 68, preferably in the form of at least one gap, is to be provided from the inner sealing section 60a into the interior of the housing. If the contact area of the exemplary H-shaped sealing area 60 should be leaking during the test, air escapes into the environment via at least channel 68 in the case of a leaking outer sealing section 60b and, in the case of a leaking inner sealing section 60a, air enters the interior of the housing 14 if a further channel 68 is present. This allows a pressure drop to be measured and it can be determined if the seal 6 is not tight. Compared to a leak test of the seal over the entire large volume of the housing, a leak test of the seal over the significantly smaller test volume 69 enclosed between the sealing sections 60a, 60b can be tested significantly faster and more accurately.

FIG. 7 shows an alternative embodiment. It differs in that the compressible element and the at least one first electrically conductive layer form a common layer 100. This means that the common layer has the properties of both the compressible element and the electrically conductive layer. The common layer 100 is preferably designed as a flat material. It can preferably be pressed in the thickness direction R.

In the illustrated embodiment, the common layer is in contact with the second electrically conductive layer 12 which runs along the inside 5 of the second housing part 4.

The contact between the common layer 100 and the second electrically conductive layer 12 ensures that the electromagnetic shielding of the housing is guaranteed.

The second housing part can also be electrically conductive itself and be a metal cover, for example. In this case, the second electrically conductive layer 12 could be omitted and the common layer 100 could be pressed directly onto the second housing part.

FIG. 8 shows another alternative embodiment. The at least one compressible element 60 and the at least one first electrically conductive layer 10 are formed as a composite flat material, wherein at least the compressible element 60 formed as a layer and/or the first electrically conductive layer 10 can be pressed in the thickness direction R.

The electrically conductive layer 10 contacts the second electrically conductive layer 12 which runs along the inside 5 of the second housing part 4. The second housing part can also be electrically conductive itself and be a metal cover, for example. In this case, the second electrically conductive layer 12 could be omitted and the first electrically conductive layer could be pressed 10 onto the second housing part.

FIG. 9 shows another alternative embodiment. It is of a structure similar to FIG. 8, with the difference that the compressible element 60 designed as a layer at least partially wraps around the at least one electrically conductive layer, in particular in the region of the circumferential edge 300 or in or on the circumferential contour.

In addition, as shown in the embodiment in FIG. 9, the at least one compressible element may have notches 400.

FIG. 10 shows a further alternative embodiment, in which the at least one electrical conductive layer 10 at least partially wraps around the at least one compressible layer 60, in particular in the region of the circumferential edge 8 or in or on the circumferential contour, In the example shown, the second housing part 4 itself is electrically conductive and can be a metal cover, for example. The first electrically conductive layer 10 makes contact with the second housing part 4. Alternatively, as shown in the previous embodiments, a second electrically conductive layer 12 can also be provided, which can contact the first electrically conductive layer 10.

FIG. 11 shows a further alternative embodiment in which at least one edge region 200 of the first electrically conductive layer 10 is rolled up or folded over. The first electrically conductive layer 10 contacts both the first housing part 2 and the second housing part 4 by the rolled-up or folded-over edge area 200.

Preferably, the electrically conductive layer 10 has an elastic or resilient behavior at least in the rolled-up or folded-over edge region 200, which results in a contact pressure on the first and second housing parts 2, 4 and the electrically conductive layer 10 itself having a sealing function.

In order to increase the sealing effect of the electrically conductive layer 10, if so required by the application, it is particularly preferable to arrange an elastic part, not shown, in the rolled-up or folded-over edge region 200, by means of which the electrically conductive layer 10 can be pressed with greater force both against the first housing part 2 and against the second housing part 4.

For even higher sealing requirements and/or faster leak testing of the seal, as described for FIG. 6, the edge area 200 of the electrically conductive layer 10 can be folded over such that two sealing beads are obtained or that two parallel sealing paths are created by an additional elastic compressible element 6 arranged parallel to the edge area 200, or that, as shown in FIG. 11, two parallel compressible elements 6 are present, which fulfill the sealing function and enable the seal to be tested, and the rolled-up or folded-over edge region 200 does not have to have a sealing function.

1. A housing preferably for accommodating electrical components, comprising
at least one first housing part and at least one second housing part, which form a closed housing when assembled,
wherein at least the first housing part has a circumferential edge or circumferential contour in an edge area, and
at least one compressible element which is at least arranged on the circumferential edge or in or on the circumferential contour and which is arranged between the first housing part and the second housing part in the assembled state,
wherein at least one first electrically conductive layer is provided, the first electrically conductive layer covering the inside of the first housing part in the assembled state of the housing.

2. The housing according to claim 1, wherein the first electrically conductive layer can contact both the first housing part and the second housing part in the area of the circumferential edge.

3. The housing according to claim 1, further comprising at least an edge region of the first electrically conductive layer that is rolled up or folded over an edge area.

4. The housing according to claim 3, wherein the first electrically conductive layer contacts both the first housing part and the second housing part by the rolled-up or folded-over edge area.

5. The housing according to claim 3, wherein the first electrically conductive layer is in contact with the compressible element by the rolled-up or folded-over edge area, the compressible element being designed as a seal.

6. The housing according to claim 3, further comprising an elastic part that can be arranged in the rolled-up or folded-over edge area, so that the electrically conductive layer can be pressed against both the first housing part and the second housing part.

7. The housing according to claim 1, wherein the at least one compressible element and the at least one first electrically conductive layer can form a common layer, which is designed as a flat material, so that the layer designed as a flat material can be compressed in the thickness direction.

8. The housing according to claim 1, wherein the at least one compressible element and the at least one first electrically conductive layer are formed as a composite flat material, wherein at least the compressible element formed as a layer and/or the first electrically conductive layer can be pressed in the thickness direction (R).

9. The housing according to claim 7, wherein the at least one compressible element designed as a compressible layer at least partially wraps around the at least one electrically conductive layer, in the region of the circumferential edge or in or on the circumferential contour.

10. The housing according to claim 8, wherein the at least one compressible element designed as a compressible layer has notches.

11. The housing according to claim 7, wherein the at least one electrically conductive layer at least partially wraps around the at least one electrically conductive layer designed as a compressible layer, in the region of the circumferential edge or in or on the circumferential contour.

12. The housing according to claim 1, wherein the at least one compressible element is designed as a seal, and wherein the seal and the first electrically conductive layer are in contact with one another.

13. The housing according to claim 12, wherein the seal is adhesively bonded to the first housing part.

14. The housing according to claim 12, wherein the seal is set on the first housing part.

15. The housing according to claim 12, wherein the contact between the seal and the electrically conductive layer is obtained by at least partial superposition and/or a form-fit and/or force-fit and/or adhesive connection is present as the contact.

16. The housing according to claim 12, wherein the seal and the electrically conductive layer form a common assembly.

17. The housing according to claim 12, wherein the seal has at least one connection area with which the electrically conductive layer is in contact.

18. The housing according to claim 17, wherein the connection region and the electrically conductive layer are arranged at least partially overlapping one another in the assembled state.

19. The housing according to claim 17, wherein the connection region is a region formed on the seal which, in the assembled state, is arranged on the side of the seal facing the inside of the housing or on the side of the seal in contact with the volume of the housing.

20. A seal for insertion into a housing according to claim 12, wherein the seal is a circumferential seal which is in contact with at least a first electrically conductive layer.
